(19) United States
(12) Patent Application Publication
(10) Pub. No.: US 2016/0285439 A1
(43) Pub. Date: Sep. 29, 2016

(54) MULTI-LEVEL CONVERSION FLIP-FLOP CIRCUITS FOR MULTI-POWER DOMAIN INTEGRATED CIRCUITS (ICs) AND RELATED METHODS

(71) Applicant: QUALCOMM Incorporated, San Diego, CA (US)

(72) Inventors: Jing Xie, San Diego, CA (US); Yang Du, Carlsbad, CA (US)

(21) Appl. No.: 14/669,030

(22) Filed: Mar. 26, 2015

(51) Int. Cl. H03K 3/3562

(52) U.S. Cl. CPC H03K 3/35625

(57) ABSTRACT

Multi-level conversion flip-flop circuits for multi-power domain integrated circuits (ICs) and related methods are disclosed. A flip-flop circuit latches a representation of a received input data signal in a lower voltage domain, in a latch circuit in a higher voltage domain without need for separate voltage level shifters. As a result, insertion loss/delay is minimized, thereby increasing performance. In certain aspects, the flip-flop circuits employ a gate-controlled, data control transistor to control activation of the latch circuit. By coupling the input data signal to a gate of the data control transistor, the input data signal in the lower voltage domain is not directly latched into the latch circuit. Instead, the data control transistor is configured to activate the latch circuit to latch a voltage in the higher voltage domain representing a logic value of the input data signal in the lower voltage domain in response to a clock signal.

### BACKGROUND

I. Field of the Disclosure

The technology of the disclosure relates generally to flip-flop circuits used in integrated circuits (ICs), and particularly to flip-flop circuits used in multi-power domain ICs.

II. Background

Processor-based systems have become commonplace throughout society due, in part, to their increasing functionality and versatility. This increase in functionality and versatility has been enabled by providing increasingly powerful processing capabilities in small packages as loosely recognized by Moore's Law. These systems require access to a power supply that provides voltage for powering operations. Some of these systems may be mobile and/or portable, and thus, may be powered through a limited power source, such as a battery. Therefore, reducing power consumption while keeping a high level of performance is of great interest.

Lower power consumption may be achieved in a processor-based system if the voltage level of the power supply providing power to the processor-based system is reduced. However, performance of the processor-based system may become degraded if the voltage level is reduced, because particular components of the processor-based system may need to operate at a higher voltage level to perform at a desired level of performance. For example, it may be desired for sequential logic circuits that are clocked by a clock signal, such as a flip-flop, to operate using a higher voltage level to maintain a higher level of performance. However, combinational logic circuits (e.g., gates) that are not clocked by the clock signal provide a better energy/performance trade off under a lower voltage level. That is, a combinational logic circuit may provide an acceptable level of performance using a lower operating voltage, and thus, less energy. In this regard, rather than providing a single higher voltage level for all components, a processor-based system can be configured to operate in multiple voltage domains, with each voltage domain operating at its own particular voltage level. Components that can operate at a lower voltage level can be powered in the lower voltage domain, which is powered by a lower voltage supply level. Components that require a higher voltage level for performance, or other reasons, can be powered in the higher voltage domain, which is powered by a higher voltage supply level. In this manner, power is conserved by the components that can operate in the lower voltage domain, as opposed to all components operating in the higher voltage domain. Such processor-based systems are generally referred to as multi-power domain integrated circuits (ICs).

For example, in particular multi-power domain ICs, to exploit a multi-power domain design in combination with a deep pipeline strategy for an optimal power performance and area (PPA) envelope, flip-flops may be designed to operate in the higher voltage domain to minimize insertion loss and increase throughput. Insertion loss is the delay from an input to an output transition of a flip-flop. However, to provide for combinational logic to operate in a lower voltage domain, voltage level shifters are employed to shift input signals from combinational logic in a lower voltage domain to a higher voltage domain to be provided as input signals to the flip-flop. For example, voltage level shifters are employed to shift an input signal in a lower voltage domain level (e.g., logic high=˜0.5 Vdd) to a higher voltage domain level (e.g., logic high=˜1.0 Vdd). The higher voltage domain signal is input as a data signal into the flip-flop operating in the higher voltage domain. Further, voltage level shifters are provided to shift output signals from the flip-flop from a higher voltage domain to a lower voltage domain before such signals reach combinational logic. However, these voltage level shifters consume area and power, and decrease throughput.

### SUMMARY OF THE DISCLOSURE

Aspects disclosed in the detailed description include multi-level conversion flip-flop circuits for multi-power domain integrated circuits (ICs). Related methods are also disclosed. In this regard, a multi-level conversion flip-flop circuit is provided that is configured to latch a representation of a received input data signal in a lower voltage domain in a latch circuit in a higher voltage domain. In this manner, the multi-level conversion flip-flop operates in the higher voltage domain to minimize insertion loss/delay, thereby increasing performance, without the need to provide separate voltage level shifters to shift the input data signal from the lower voltage domain to the higher voltage domain. Furthermore, combinational logic can operate at a lower voltage level to reduce power consumption. Further still, area and power may be conserved as a result of eliminating the separate voltage level shifters at input and output stages of the flip-flop.

In this regard, in certain aspects disclosed herein, to allow a representation of the input data signal in the lower voltage domain to be latched in a latch circuit in the higher voltage domain, the multi-level conversion flip-flop circuits employ gate-controlled, control transistors. The gate-controlled, control transistors control activation of the latch circuit operating in the higher voltage domain. The gate-controlled, control transistors include a clock control transistor, gated by a clock signal, coupled to a data control transistor, gated by the input data signal. By coupling the input data signal to the gate of the data control transistor, the input data signal in the lower voltage domain is not directly latched into the latch circuit. Instead, the gate-controlled, control transistors are configured to activate or control the latch circuit to latch a voltage in the higher voltage domain representing a logic value of the input data signal in the lower voltage domain in response to the clock signal. This allows for a level shift from the lower voltage domain to the higher voltage domain to occur within the multi-level conversion flip-flop circuits without the need to provide a separate voltage level shifter to voltage level shift the input data signal into the higher voltage domain before being input into the multi-level conversion flip-flop circuit.

Further, providing a gate-controlled data transistor in the multi-level conversion flip-flop circuits can provide other non-limiting benefits. For example, because the latch circuit is activated by the data control transistor, the latch circuit is not activated unless there is a state change in the input data signal. This reduces dynamic power, thereby reducing power consumption and contributing to the circuit's stability, as opposed to the latch circuit latching the input data signal every clock cycle even if the input data signal level has not changed. Also, providing the data control transistor can avoid or reduce voltage drift of the input data signal. This is as opposed to a drain/source connection in a pass/transmission transistor configuration that propagates the input data signal through the pass/transmission transistor's channel. Avoiding voltage drift can provide for more stable operation of multi-level conversion flip-flop circuits than when using a pass/transmission transistor.

In this regard, in one aspect, a flip-flop circuit is provided. The flip-flop circuit comprises an input stage in a lower voltage domain. The input stage is configured to receive an input data signal on a data input in the lower voltage domain and a clock signal on a clock input. The flip-flop circuit also comprises a master stage in a higher voltage domain than the lower voltage domain. The master stage comprises a control circuit. The control circuit comprises a clock control transistor including a gate electrode configured to receive the clock signal, a first current electrode, and a second current electrode coupled to a first current electrode of a data control transistor. The data control transistor comprises a gate electrode coupled to the data input to receive the input data signal, the first current electrode coupled to the second current electrode of the clock control transistor, and a second current electrode. The control circuit is configured to generate a control signal based on an activation of the clock control transistor by the clock signal and the data control transistor by the input data signal.

The master stage further comprises a latch circuit. The latch circuit comprises a first latch node coupled to the control circuit to receive the control signal. The latch circuit is configured to store a latched voltage as a first latched input data in the higher voltage domain, based on the input data signal in response to the control signal from the control circuit. The flip-flop circuit further comprises a slave stage in the higher voltage domain. The slave stage is configured to receive the first latched input data from the master stage and latch the first latched input data as a second latched output data. The flip-flop circuit further comprises an output stage. The output stage is configured to provide the second latched output data as a flip-flop output.

In another aspect, a flip-flop circuit is provided. The flip-flop circuit comprises a means for receiving an input data signal on a data input in a lower voltage domain. The flip-flop circuit further comprises a means for receiving a clock signal on a clock input. The flip-flop circuit further comprises a means for controlling a means for latching. The means for controlling comprises a clock control means for receiving the clock signal at a gate electrode and coupling a first current electrode of the clock control means to a first current electrode of a data control means in response to the clock signal. The data control means is for receiving the input data signal at a gate electrode and coupling the first current electrode of the data control means to a second current electrode of the data control means in response to the input data signal. The means for latching is for storing a latched voltage as a first latched input data in a higher voltage domain based on the input data signal, in response to the clock control means and the data control means. The flip-flop circuit further comprises a means for receiving the first latched input data from the means for latching, and latching the first latched input data as a second latched output data. The flip-flop circuit further comprises a means for outputting the second latched output data as a flip-flop output.

In another aspect, a method for latching an input data signal in a flip-flop circuit is provided. The method comprises receiving, at an input stage, an input data signal on a data input in a lower voltage domain. The method further comprises receiving, at the input stage, a clock signal on a clock input. The method further comprises receiving the clock signal at a gate electrode of a clock control transistor. The clock control transistor comprises a first current electrode and a second current electrode coupled to a first current electrode of a data control transistor. The method further comprises receiving the input data signal at a gate electrode of the data control transistor. The data control transistor comprises the first current electrode coupled to the second current electrode of the clock control transistor, and a second current electrode. The method further comprises generating a control signal based on an activation of the clock control transistor by the clock signal and the data control transistor by the input data signal. The method further comprises storing a latched voltage as a first latched input data at a first latch node in a higher voltage domain than the lower voltage domain, based on the input data signal in response to the control signal. The method further comprises latching the first latched input data as a second latched output data in a slave stage. The method further comprises outputting the second latched output data as a flip-flop output.

### BRIEF DESCRIPTION OF THE FIGURES

FIG. 1 is a schematic diagram of an exemplary multi-power domain integrated circuit (IC) including an exemplary multi-level conversion flip-flop circuit that receives an input data signal in a lower voltage domain and latches a voltage representing a logic level of the input data signal in a higher voltage domain to provide a higher voltage domain flip-flop output without the need for separate voltage level shifters outside the multi-level conversion flip-flop circuit;

FIG. 2 is a flowchart illustrating an exemplary operation of the multi-level conversion flip-flop circuit in FIG. 1;

FIG. 3 is a schematic diagram of the multi-level conversion flip-flop circuit in FIG. 1 illustrating additional detail of an exemplary latch circuit provided therein;

FIG. 4 is a schematic diagram of an exemplary multi-level conversion flip-flop circuit that additionally includes an exemplary head pair transistor circuit configured to control providing a higher voltage in a higher voltage domain to a latch circuit;

FIG. 5 is a schematic diagram of another exemplary multi-level conversion flip-flop circuit that includes an alternative exemplary head pair transistor circuit configured to control providing a higher voltage in a higher voltage domain to a latch circuit; and

FIG. 6 is a block diagram of an exemplary processor-based system that can include the multi-level conversion flip-flop circuit of FIG. 1.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include multi-level conversion flip-flop circuits for multi-power domain integrated circuits (ICs). Related methods are also disclosed. In this regard, a multi-level conversion flip-flop circuit is provided that is configured to latch a representation of a received input data signal in a lower voltage domain in a latch circuit in a higher voltage domain. In this manner, the multi-level conversion flip-flop operates in the higher voltage domain to minimize insertion loss/delay, thereby increase performance, without the need to provide separate voltage level shifters to shift the input data signal from the lower voltage domain to the higher voltage domain. Furthermore, combinational logic can operate at a lower voltage level to reduce power consumption. Further still, area and power may be conserved as a result of eliminating the separate voltage level shifters at input and output stages of the flip-flop.

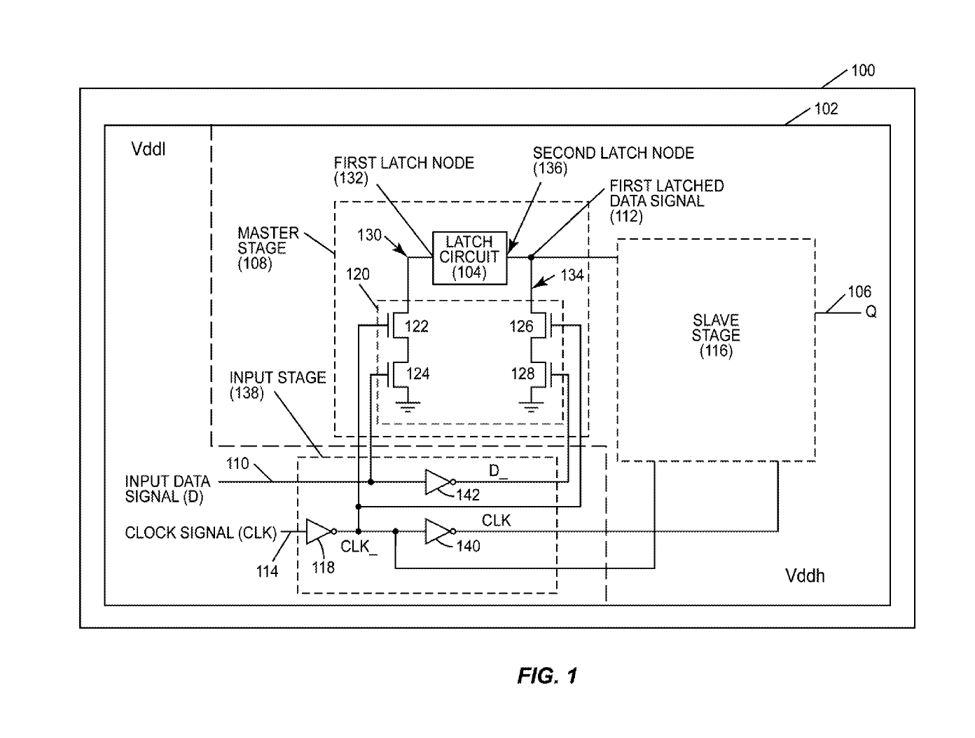

In this regard, FIG. 1 illustrates a multi-power domain integrated circuit (IC) 100 including a multi-level conversion flip-flop circuit 102. In FIG. 1, the multi-level conversion flip-flop circuit 102 is provided as a dual-level conversion flip-flop circuit 102. As will be discussed in more detail below, the dual-level conversion flip-flop circuit 102 is configured to latch a representation of a received input data signal D in a lower voltage domain Vddl in a latch circuit 104 in a higher voltage domain Vddh. The dual-level conversion flip-flop circuit 102 operates in the higher voltage domain Vddh to minimize insertion loss/delay, thereby increasing performance, without the need to provide separate voltage level shifters to shift the input data signal D from the lower voltage domain Vddl to the higher voltage domain Vddh.

With reference to FIG. 1, as will be discussed in more detail, the dual-level conversion flip-flop circuit 102 provides a flip-flop output 106 with a latched representation (flip-flop output signal Q) of the received input data signal D received in the lower voltage domain Vddl. The latching process is performed in the higher voltage domain Vddh. The dual-level conversion flip-flop circuit 102 includes a master stage 108 that is configured to latch a representation of the input data signal D received on a data input 110 in the lower voltage domain Vddl into the higher voltage domain Vddh as a first latched data signal 112 in the master stage 108. The master stage 108 is clocked by a clock signal CLK received on a clock input 114. The first latched data signal 112 is provided to a slave stage 116 to be latched as a second latched data signal therein (not shown) in a subsequent clock signal CLK transition. The second latched data signal is provided to the flip-flop output 106 to provide a flip-flop output signal Q representing a logic level of the input data signal D received by the dual-level conversion flip-flop circuit 102 in the lower voltage domain Vddl.

In this example, an inverter 118 is coupled between the clock input 114 and clock control transistors 122 and 126 such that the signal activating the clock control transistors 122 and 126 is an inverted representation of the clock signal CLK (CLK_), and such that the active state of the clock signal CLK is a fall-edge transition. However, the dual-level conversion flip-flop circuit 102 could be configured for the clock signal CLK active state to be the rising edge of the clock signal CLK. Throughout the disclosure both the clock signal CLK and the inverted representation of the clock signal CLK (CLK_) may be referred to as clock signals CLK and CLK_, respectively.

With continuing reference to FIG. 1, to allow the input data signal D in the lower voltage domain Vddl to be latched in the latch circuit 104 in the higher voltage domain Vddh within the dual-level conversion flip-flop circuit 102, the dual-level conversion flip-flop circuit 102 employs a control circuit 120, including gate-controlled, control transistors 122-128. In this manner, the input data signal D is not directly coupled to the latch circuit 104, which operates in the higher voltage domain Vddh.

The gate-controlled, control transistors 122-128 include a clock control transistor 122 gated by the clock signal CLK_, coupled to a data control transistor 124 gated by the input data signal D. The clock control transistor 122 and the data control transistor 124 are coupled together in an ANDing configuration. When the clock control transistor 122 and the data control transistor 124 are activated, they generate a control signal 130 at a first latch node 132 corresponding to a ground level connection. When at least one of the clock control transistor 122 and the data control transistor 124 is not activated, they generate a floating state at the first latch node 132, which allows the latch circuit 104 to drive the control signal 130 in the higher voltage domain Vddh.

The gate-controlled, control transistors 122-128 further include a clock control transistor 126 gated by the clock signal CLK_, coupled to a data control transistor 128 gated by an inverted representation of input data signal D (D_). The clock control transistor 126 and the data control transistor 128 are coupled together in an ANDing configuration. When the clock control transistor 126 and the data control transistor 128 are activated, they generate a control signal 134 at a second latch node 136 corresponding to the ground level connection. When at least one of the clock control transistor 126 and the data control transistor 128 is not activated, they generate a floating state at the second latch node 136, which allows the latch circuit 104 to drive the control signal 134 in the higher voltage domain Vddh.

By coupling the input data signal D and the inverted input data signal D_ to the gates of the data control transistors 124 and 128, respectively, the input data signal D in the lower voltage domain Vddl is not directly latched into the latch circuit 104. Instead, the gate-controlled, control transistors 122-128 are configured to control the latch circuit 104 to latch a voltage in the higher voltage domain Vddh representing the logic value of the input data signal D in the lower voltage domain Vddl in response to the clock signal CLK_. This allows for a level shift from the lower voltage domain Vddl to the higher voltage domain Vddh to occur within the dual-level conversion flip-flop circuit 102 without the need to provide a separate voltage level shifter to voltage level shift the input data signal D into the higher voltage domain Vddh before being input into the dual-level conversion flip-flop circuit 102.

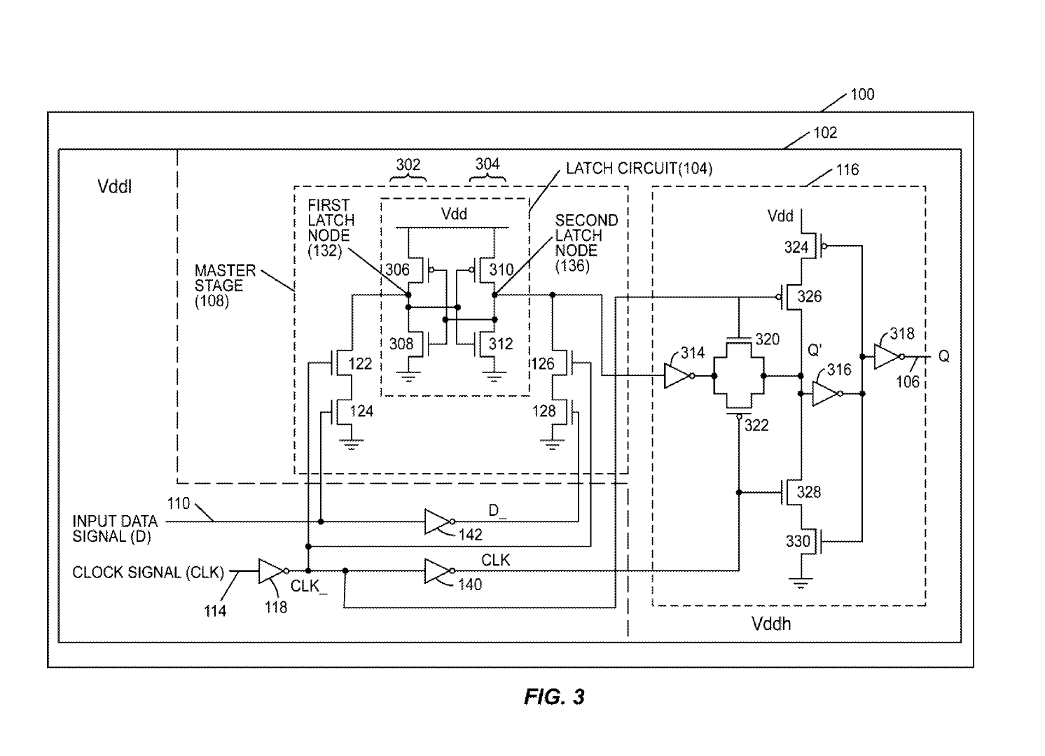

With continuing reference to FIG. 1, the dual-level conversion flip-flop circuit 102 further includes an input stage 138 to receive the input data signal D on the data input 110 in the lower voltage domain Vddl and the clock signal CLK on the clock input 114. The input stage 138 includes the inverter 118 coupled to the clock input 114 to provide the clock signal CLK_. The input stage 138 further includes a clock inverter 140 for providing a logical copy of the clock signal CLK to the slave stage 116. The slave stage 116 will be explained in further detail below with reference to FIG. 3. The input stage 138 further includes a data inverter 142 coupled to the data input 110 to provide the inverted input data signal D_.

The aspects described above with reference to the gate-controlled, control transistors 122-128 can provide additional non-limiting benefits to a multi-level conversion flip-flop circuit, such as the dual-level conversion flip-flop circuit 102 of FIG. 1. For example, conventional latch circuits are activated in every clock cycle, even if the input data signal level has not changed. In exemplary multi-level conversion flip-flop circuits, because the latch circuit is activated by a data control transistor that is gate-controlled by an input data signal, the latch circuit is not activated (i.e., forced to store a new voltage level) unless there is a state change in the input data signal. This allows for a reduction in dynamic power, thereby reducing power consumption and contributing to the circuit's stability. Also, conventionally, an input data signal in a flip-flop circuit may be provided to a drain/source connection of a pass/transmission transistor, such that the input data signal propagates through the pass/transmission transistor's channel, which causes voltage drift in the input data signal. In exemplary multi-level conversion flip-flop circuits, the input data signal is provided as a gate input of the data control transistor, which avoids or reduces voltage drift of the input data signal. Avoiding voltage drift can provide for more stable operation of multi-level conversion flip-flop circuits than when using a pass/transmission transistor.

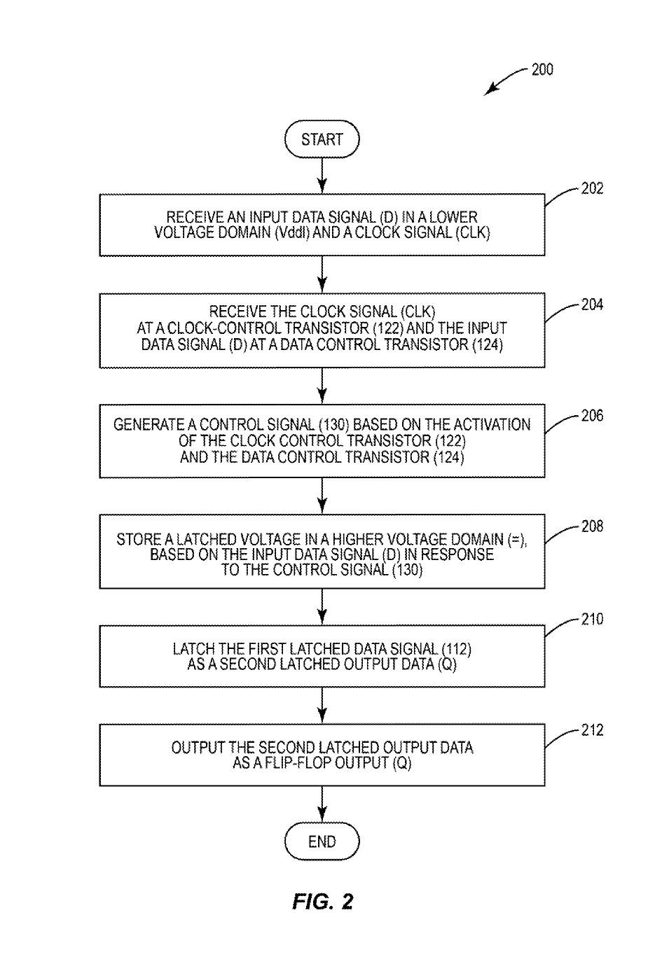

With the above description of the components of the dual-level conversion flip-flop circuit 102, a more detailed discussion of the operation of the dual-level conversion flip-flop circuit 102 will now be provided with reference to the flowchart in FIG. 2. In this regard, FIG. 2 is a flowchart 200 illustrating an exemplary operation of the dual-level conversion flip-flop circuit 102 in FIG. 1. The components referenced herein corresponding to those shown in FIG. 1 are designated by the same reference numbers and will not be described in detail.

First, the dual-level conversion flip-flop circuit 102 receives an input data signal D in a lower voltage domain Vddl and a clock signal CLK (block 202). The clock control transistor 122 receives the clock signal CLK and the data control transistor 124 receives the input data signal D (block 204). The dual-level conversion flip-flop circuit 102 generates a control signal 130 based on the activation of a clock control transistor by the activation of the clock control transistor 122 and the data control transistor 124 (block 206). The dual-level conversion flip-flop circuit 102 then stores a latched voltage in the higher voltage domain Vddh as a first latched data signal 112, based on the input data signal D in response to the control signal 130 (block 208). The dual-level conversion flip-flop circuit 102 latches the first latched data signal 112 as a second latched output data Q′ (block 210). The dual-level conversion flip-flop circuit 102 outputs the second latched output data Q′ as a flip-flop output Q (block 212).

As discussed above, the dual-level conversion flip-flop circuit 102 is configured to latch a representation of an input data signal D, received in the lower voltage domain Vddl, in a latch circuit 104 in the higher voltage domain Vddh. One way to provide such a latch circuit 104 is to provide the input data signal D and the clock signal CLK as control signals to control transistors of a cross-coupled inverter circuit. The cross-coupled inverter circuit may store a representation of the input data signal D in a manner similar to how a 6-transistor (6T) configuration static random access memory (6T SRAM) stores data. Gate-controlled, control transistors controlled by the input data signal D may be used to store the representation of the input data signal D in the cross-coupled inverter circuit operating in the higher voltage domain Vddh. Furthermore, gate-controlled, control transistors controlled the clock signal CLK may be used to control the timing for latching the representation of the input data signal D in the cross-coupled inverter circuit operating in the higher voltage domain Vddh. In this manner, the clock and data control transistors control activation of the cross-coupled inverter circuit to set the voltage level stored in an output node of the cross-coupled inverter circuit based on the clock signal CLK and the input data signal D.

In this regard, FIG. 3 illustrates the multi-power domain IC 100 of FIG. 1, including further detail regarding the latch circuit 104. The components identical to those shown in FIG. 1 are designated by the same reference numbers and will not be described in detail. FIG. 3 illustrates the latch circuit 104 of the dual-level conversion flip-flop circuit 102 illustrated in FIG. 1, expanded to reveal its internal transistor configurations. The latch circuit 104 includes a first inverter 302 and a second inverter 304, configured as a cross-coupled inverter circuit for storing a voltage level in the higher voltage domain Vddh. The latch circuit 104 includes a P-type metal-oxide-semiconductor (PMOS) transistor 306 and an N-type metal-oxide-semiconductor (NMOS) transistor 308, wherein the respective gates of the PMOS transistor 306 and the NMOS transistor 308 are connected to form an input of the first inverter 302. Also, each of the PMOS transistor 306 and the NMOS transistor 308 has one of their respective current electrodes connected to form an output of the first inverter 302. A remaining current electrode of the PMOS transistor 306 is connected to a voltage source of the higher voltage domain Vddh. A remaining current electrode of the NMOS transistor 308 is connected to a ground level connection of the dual-level conversion flip-flop circuit 102. Therefore, the PMOS transistor 306 and the NMOS transistor 308 are activated in a complementary manner. When a high logic state is present at the input of the first inverter 302, the NMOS transistor 308 is turned on and the PMOS transistor 306 is turned off, thereby causing a low logic state to be generated at the output of the first inverter 302. When a low logic state is present at the input of the first inverter 302, the NMOS transistor 308 is turned off and the PMOS transistor 306 is turned on, thereby causing a high logic state to be generated at the output of the first inverter 302.

The latch circuit 104 further includes a PMOS transistor 310 and an NMOS transistor 312, wherein the respective gates of the PMOS transistor 310 and the NMOS transistor 312 are connected to form an input of the second inverter 304. Also, each of the PMOS transistor 310 and the NMOS transistor 312 has one of their respective current electrodes connected to form an output of the second inverter 304. A remaining current electrode of the PMOS transistor 310 is connected to the voltage source of the higher voltage domain Vddh. A remaining current electrode of the NMOS transistor 312 is connected to the ground level connection of the dual-level conversion flip-flop circuit 102. The PMOS transistor 310 and the NMOS transistor 312 are activated in a complementary manner similar to how the PMOS transistor 306 and the NMOS transistor 308 are activated, and thus, their activation will not be explained further.

FIG. 3 further shows the slave stage 116 for latching data stored at the latch circuit 104, expanded to reveal its internal transistor configurations. The slave stage 116 separates the output of the master stage 108 (the value latched by the latch circuit 104 and provided at the second latch node 136) from an second latched data signal Q′ and the flip-flop output signal Q of the dual-level conversion flip-flop circuit 102. The slave stage 116 also provides the latched output Q in the lower voltage domain Vddl. The slave stage 116 includes inverters 314-318 and transistors 320-330. Inverter 318 operates in the lower voltage domain Vddl, and thus, level-shifts the output from the master stage 108 from the higher voltage domain Vddh to the lower voltage domain Vddl. Accordingly, the inverter 318 may also be referred to as a level shifting circuit.

With continuing reference to FIG. 3, in operation, when the clock signal CLK is low, the clock signal CLK_ is high. The output of the master stage 108 is propagated through the inverters 314-318 to provide the logic level at the output of the master stage 108 as the logic level at the output of the inverter 318, which is not yet latched by the slave stage 116. When the clock signal CLK is high, the clock signal CLK_ is low, which closes the path through the inverters 314-318 at transistors 320 and 322, and the output of the inverter 318 becomes latched as latched output Q.

Although the dual-level conversion flip-flop circuit 102, described with reference to FIGS. 1-3 can latch a representation of a received input data signal D in a lower voltage domain Vddl in the latch circuit 104 in a higher voltage domain Vddh, transitions in the latched representation are still subject to dynamic power loss. For example, when the value latched at the latch circuit 104 is logic high, the voltage level at the first latch node 132 is low and the voltage level at the second latch node 136 is high. During a transition from high to low, the data control transistor 128 becomes active because its gate is controlled by the inverted input data signal D_. When the clock control transistor 126 becomes active (CLK_ becomes high), a path between a voltage and ground level is established momentarily until the cross-coupled inverter structure reaches a steady state, and the value at the second latch node 136 becomes low, thus causing a dynamic power loss.

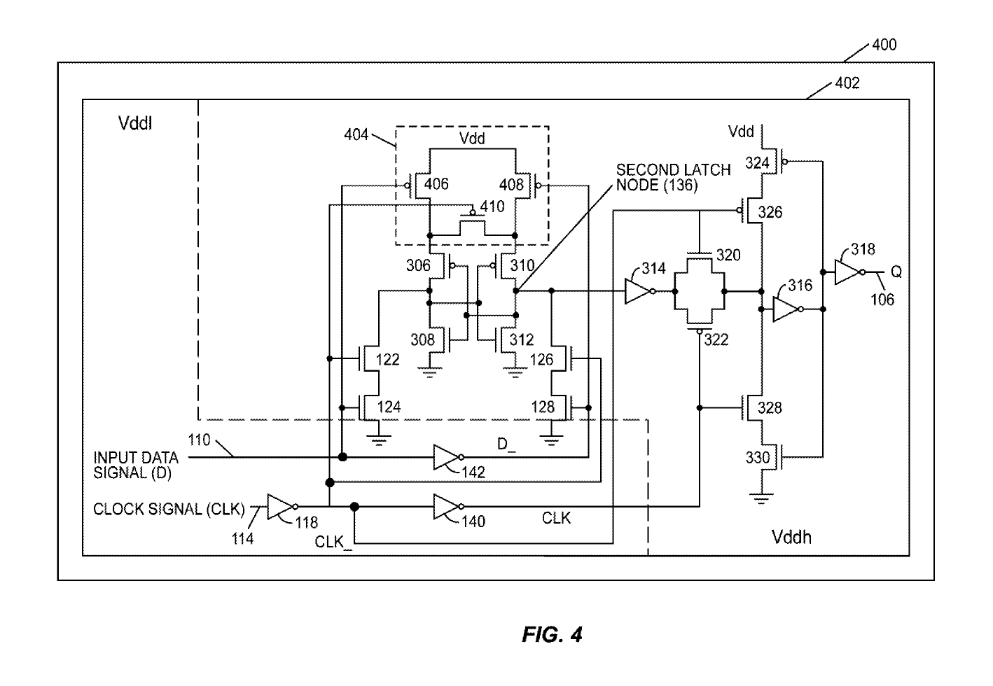

In this regard, FIG. 4 illustrates a multi-power domain IC 400 including a multi-level conversion flip-flop circuit 402, further including a head pair transistor circuit 404 for reducing dynamic power loss. The components identical to those shown in FIGS. 1 and 3 are designated by the same reference numbers and will not be described in detail.

With reference to FIG. 4, the head pair transistor circuit 404 includes a PMOS transistor 406 having a first current electrode coupled to a voltage source Vdd of the higher voltage domain Vddh, a gate electrode coupled to the input data signal D, and a second current electrode coupled to a current electrode of the PMOS transistor 306. The head pair transistor circuit 404 further includes a PMOS transistor 408 having a first current electrode coupled to the voltage source Vdd, a gate electrode coupled to the inverted input data signal D_, and a second current electrode coupled to a current electrode of the PMOS transistor 310. When the input data signal D is in a low logic state and the inverted input data signal D_ being in a high logic state, the PMOS transistor 406 is turned on and the PMOS transistor 408 is turned off, thereby causing the voltage source Vdd to reach a power input of the first inverter 302 of the cross-coupled inverter circuit of the latch circuit 104 (the current electrode of the PMOS transistor 306) and a floating state in a power input of the second inverter 304 of the cross-coupled inverter circuit of the latch circuit 104 (current electrode of PMOS transistor 310). When the input data signal D is in a high logic state and the inverted input data signal D_ is in a low logic state, the PMOS transistor 406 is turned off and the PMOS transistor 408 is turned on, thereby causing the voltage source Vdd to reach the power input of the second inverter 304 and a floating state in the power input of the first inverter 302.

The head pair transistor circuit 404 further includes a PMOS transistor 410, having a first electrode coupled to the second current electrode of the PMOS transistor 406 and to the power input of the first inverter 302, a gate electrode coupled to the clock signal CLK_, and a second electrode coupled to the second current electrode of the PMOS transistor 408 and to the power input of the second inverter 304. Thus, the PMOS transistor 410 functions as a bridge transistor between the power input of the first inverter 302 and the power input of the second inverter 304. When the clock signal CLK is in a high logic state, the clock signal CLK_ is in a low logic state, and the PMOS transistor 410 is turned on, thereby causing the voltage source Vdd to reach the power input of the first and second inverters 302 and 304, independent of the input data signal D being in a high logic state or a low logic state. When the clock signal CLK is in a low logic state, the clock signal CLK_ is in a high logic state, and the PMOS transistor 410 is turned off, thereby causing the voltage source Vdd to reach the power input of only one of the first and second inverters 302 and 304, based on the state of the input data signal D.

Accordingly, when the clock signal CLK is in a low logic state, the clock signal CLK_ is in a high logic state, which turns on the clock control transistor 122 and the clock control transistor 126, allowing the writing of the logic value of the input data signal D into the latch circuit 104. Setting the clock signal CLK_ in a high logic state turns the PMOS transistor 410 off and allows the voltage source Vdd to reach the power input of only one of the first and second inverters 302 and 304, based on the state of the input data signal D. In particular, setting the clock signal CLK_ in a high logic state turns the PMOS transistor 410 off and allows the voltage source Vdd to reach a power input of one of the two inverters. The powered inverter uses the voltage for latching the representation of the input data signal D into the latch circuit 104. The other inverter does not receive the voltage This prevents the establishment of a path between the voltage source Vdd and ground level during the period in which the cross-coupled inverter structure reaches steady state, thus reducing a dynamic power loss.

For example, when the input data signal D is a logic high, the head pair transistor circuit 404 provides the voltage source Vdd only to the second inverter 304, which requires the voltage source Vdd in order to set the second latch node 136 to a logic high in the higher voltage domain Vddh. Accordingly, head pair transistor circuit 404 does not create a path between the voltage source Vdd and ground level while the cross-coupled inverter structure reaches a steady state, thus reducing dynamic power loss.

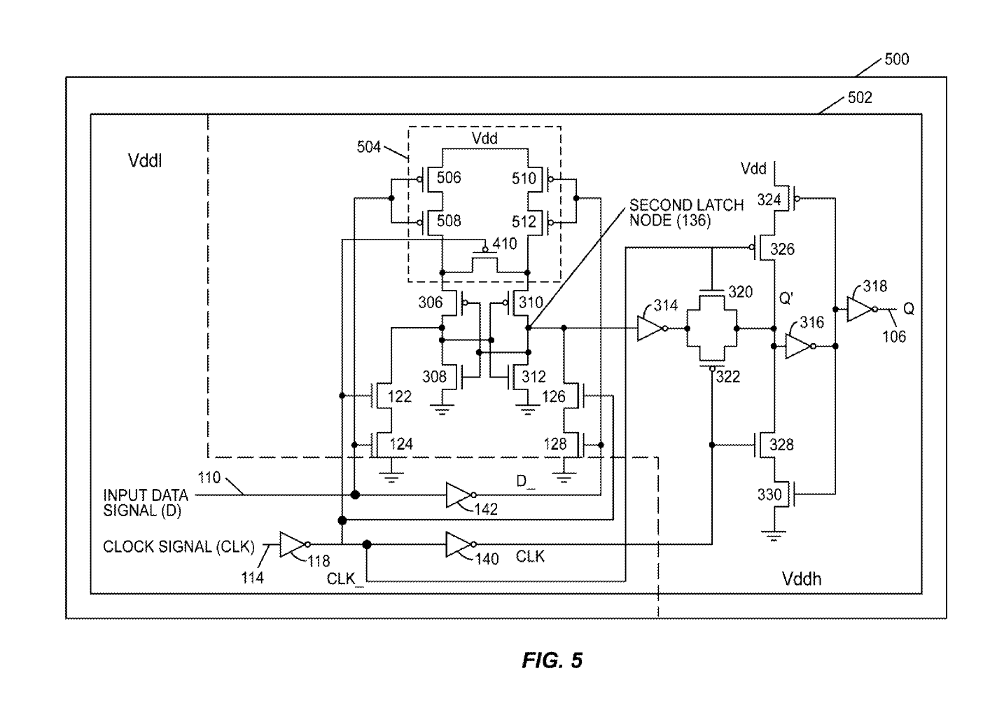

FIG. 5 illustrates a multi-power domain IC 500 including a multi-level conversion flip-flop circuit 502, further including a head pair transistor circuit 504 for reducing dynamic power loss. The multi-power domain IC 500 is similar to the multi-power domain IC 400 illustrated in FIG. 4, differing only in the configuration/structure of its corresponding head pair transistor circuits 404 and 504. The components identical to those shown in FIGS. 1, 3, and 4 are designated by the same reference numbers and will not be described in detail.

In detail, the head pair transistor circuit 504 of FIG. 5 includes a first transistor stack including PMOS transistors 506 and 508, having a gate electrode coupled to the input data signal D, and a second transistor stack including PMOS transistors 510 and 512, having a gate electrode coupled to the inverted input data signal D_. In operation, the first transistor stack operates similar to the PMOS transistor 406 illustrated in FIG. 4 and described above, and the second transistor stack operates similar to the PMOS transistor 408 illustrated in FIG. 4 and described above. Accordingly, their logical functionality within the latching process will not be described in detail. This configuration allows a faster write time in the master stage, which saves power and enhances setup time in the design.

The multi-level conversion flip-flop circuits for multi-power domain ICs and related methods according to aspects disclosed herein may be provided in or integrated into any processor-based device. Examples, without limitation, include a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

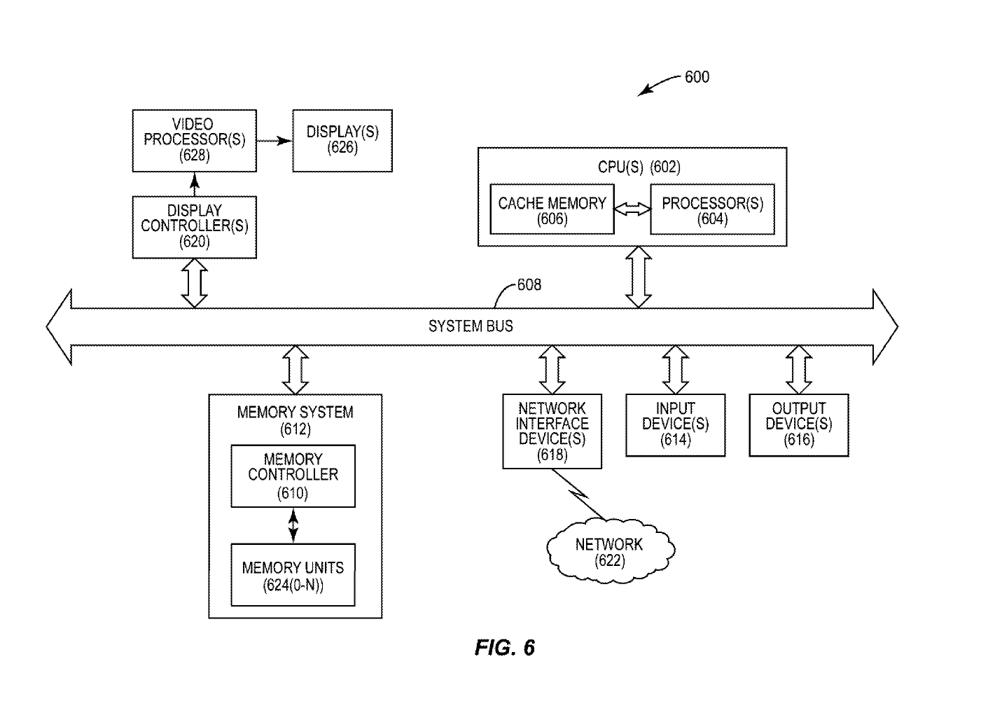

In this regard, FIG. 6 illustrates an example of a processor-based system 600 that can employ a dual-level conversion flip-flop circuit according to any of the embodiments disclosed herein, including the dual-level conversion flip-flop circuit 102, 402, and 502 in FIGS. 1, 4, and 5, respectively. In this example, the processor-based system 600 includes one or more central processing units (CPUs) 602, each including one or more processors 604. The CPU(s) 602 may have cache memory 606 coupled to the processor(s) 604 for rapid access to temporarily stored data. The CPU(s) 602 is coupled to a system bus 608 and can intercouple master and slave devices that may be included in the processor-based system 600. As is well known, the CPU(s) 602 communicates with these other devices by exchanging address, control, and data information over the system bus 608. For example, the CPU(s) 602 can include a master device that communicates bus transaction requests to a memory controller 610 as an example of a slave device. Although not illustrated in FIG. 6, multiple system buses similar to the system bus 608 could be provided, wherein each system bus constitutes a different fabric.

Other master and slave devices can be connected to the system bus 608. As illustrated in FIG. 6, these devices can include a memory system 612, one or more input devices 614, one or more output devices 616, one or more network interface devices 618, and one or more display controllers 620, as examples. The input device(s) 614 can include any type of input device, including but not limited to input keys, switches, voice processors, etc. The output device(s) 616 can include any type of output device, including but not limited to audio, video, other visual indicators, etc. The network interface device(s) 618 can be any devices configured to allow exchange of data to and from a network 622. The network 622 can be any type of network, including but not limited to a wired or wireless network, a private or public network, a local area network (LAN), a wireless local area network (WLAN), a wide area network (WAN), a BLUETOOTH™ network, and the Internet. The network interface device(s) 618 can be configured to support any type of communications protocol desired. The memory system 612 can include one or more memory units 624(0-N).

The CPU(s) 602 may also be configured to access the display controller(s) 620 over the system bus 608 to control information sent to one or more displays 626. The display controller(s) 620 sends information to the display(s) 626 to be displayed via one or more video processors 628, which process the information to be displayed into a format suitable for the display(s) 626. The display(s) 626 can include any type of display, including but not limited to a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium and executed by a processor or other processing device, or combinations of both. The master devices and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow chart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A flip-flop circuit, comprising:
an input stage in a lower voltage domain, the input stage configured to receive an input data signal on a data input in the lower voltage domain and a clock signal on a clock input;
a master stage in a higher voltage domain than the lower voltage domain, the master stage comprising:
a control circuit, comprising:
a clock control transistor comprising: a gate electrode configured to receive the clock signal, a first current electrode, and a second current electrode coupled to a first current electrode of a data control transistor;
the data control transistor comprising: a gate electrode coupled to the data input to receive the input data signal, the first current electrode coupled to the second current electrode of the clock control transistor, and a second current electrode; and
the control circuit configured to generate a control signal based on an activation of the clock control transistor by the clock signal and the data control transistor by the input data signal; and
a latch circuit comprising a first latch node coupled to the control circuit to receive the control signal, the latch circuit configured to store a latched voltage as a first latched input data in the higher voltage domain, based on the input data signal in response to the control signal from the control circuit;
a slave stage in the higher voltage domain, the slave stage configured to receive the first latched input data from the master stage and latch the first latched input data as a second latched output data; and
an output stage configured to provide the second latched output data as a flip-flop output.

2. The flip-flop circuit of claim 1,
the input stage further comprising:
a data inverter comprising: a signal input coupled to the data input configured to receive the input data signal, a data inverting output, and a power input coupled to a voltage source of the lower voltage domain; and
the control circuit further comprising:
a second clock control transistor comprising: a gate electrode configured to receive the clock signal, a first current electrode, and a second current electrode coupled to a first current electrode of a second data control transistor;
the second data control transistor comprising: a gate electrode coupled to the data inverting output of the data inverter configured to receive an inverted input data signal, the first current electrode coupled to the second current electrode of the second clock control transistor, and a second current electrode;
the control circuit further configured to generate a second control signal based on an activation of the second clock control transistor by the clock signal and the second data control transistor by the inverted input data signal; and
the latch circuit further comprising a second latch node coupled to the control circuit configured to receive the second control signal, the latch circuit configured to store the latched voltage as the first latched input data in the higher voltage domain, based on the input data signal in response to the control signal and the second control signal from the control circuit.

3. The flip-flop circuit of claim 2,
the latch circuit further comprising:
a first inverter comprising a signal input coupled to the first latch node, an inverting output coupled to a signal input of a second inverter and to the second latch node, and a power input coupled to a voltage source of the higher voltage domain; and
the second inverter comprising the signal input coupled to the inverting output of the first inverter and to the second latch node, an inverting output coupled to the signal input of the first inverter and to the first latch node, and a power input coupled to the voltage source of the higher voltage domain;
the latch circuit configured to store the first latched input data in the higher voltage domain at the second latch node; and
the slave stage configured to receive the first latched input data from the second latch node.

4. The flip-flop circuit of claim 3, the master stage further comprising a head pair transistor circuit, comprising:
a first transistor having a first current electrode coupled to the voltage source of the higher voltage domain, a gate electrode coupled to the data input configured to receive the input data signal, and a second current electrode coupled to the power input of the first inverter, the first transistor configured to couple the voltage source of the higher voltage domain to the power input of the first inverter based on the input data signal;
a second transistor having a first current electrode coupled to the voltage source of the higher voltage domain, a gate electrode coupled to the data inverting output of the data inverter configured to receive the inverted input data signal, and a second current electrode coupled to the power input of the second inverter, the second transistor configured to couple the voltage source of the higher voltage domain to the power input of the second inverter based on the data inverting output of the data inverter; and
a bridge transistor having a first electrode coupled to the second current electrode of the first transistor and to the power input of the first inverter, a gate electrode configured to receive the clock signal, and a second electrode coupled to the second current electrode of the second transistor and the power input of the second inverter, the bridge transistor configured to couple the second current electrode of the first transistor and the second current electrode of the second transistor to control coupling of the voltage source of the higher voltage domain to the power input of the first inverter and to the power input of the second inverter based on the clock signal.

5. The flip-flop circuit of claim 1, the slave stage further comprising a level-shifting circuit configured to level-shift the second latched output data from the higher voltage domain to the lower voltage domain and provide the level-shifted second latched output data on the flip-flop output.

6. The flip-flop circuit of claim 1, wherein the first latch node of the latch circuit is coupled to the control circuit at the first current electrode of the clock control transistor, and the control circuit is configured to provide the control signal at the first current electrode of the clock control transistor.

7. The flip-flop circuit of claim 1, wherein the first latch node of the latch circuit is coupled to the control circuit at the second current electrode of the data control transistor, and the control circuit is configured to provide the control signal at the second current electrode of the data control transistor.

8. The flip-flop circuit of claim 1 integrated into an integrated circuit (IC).

9. The flip-flop circuit of claim 1 integrated into a device selected from the group consisting of: a set top box; an entertainment unit; a navigation device; a communications device; a fixed location data unit; a mobile location data unit; a mobile phone; a cellular phone; a computer; a portable computer; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; and a portable digital video player.

10. A flip-flop circuit, comprising:
a means for receiving an input data signal on a data input in a lower voltage domain;
a means for receiving a clock signal on a clock input;
a means for controlling a means for latching, the means for controlling comprising:
a clock control means for receiving the clock signal at a gate electrode and coupling a first current electrode of the clock control means to a first current electrode of a data control means in response to the clock signal;
the data control means for receiving the input data signal at a gate electrode and coupling the first current electrode of the data control means to a second current electrode of the data control means in response to the input data signal; and
the means for latching for storing a latched voltage as a first latched input data in a higher voltage domain based on the input data signal, in response to the clock control means and the data control means;
a means for receiving the first latched input data from the means for latching, and latching the first latched input data as a second latched output data; and
a means for outputting the second latched output data as a flip-flop output.

11. The flip-flop circuit of claim 10, wherein:
the means for receiving further comprises a means for inverting the input data signal and providing an inverted input data signal in the lower voltage domain; and
the means for latching further comprises:
a second clock control means for receiving the clock signal at a gate electrode and coupling a first current electrode of the second clock control means to a first current electrode of a second data control means in response to the clock signal; and
the second data control means for receiving the input data signal at a gate electrode and coupling the first current electrode the data control means to the second current electrode of the second data control means in response to the input data signal; and
the means for latching for storing the latched voltage as the first latched input data in the higher voltage domain based on the input data signal, in response to the clock control means, the second clock control means, the data control means, and the second data control means.

12. The flip-flop circuit of claim 11, wherein:
the means for latching further comprises:
a first means for inverting coupled to a first latch node for inverting a signal received from the first latch node and providing an inverted latch node signal to a second means for inverting and to a second latch node, in the higher voltage domain; and
the second means for inverting coupled to the first means for inverting and to the second latch node for inverting the signal received from the first means for inverting and from the second latch node, and providing an inverted second latch node signal to the first means for inverting and to the first latch node, in the higher voltage domain;
the means for latching is configured to store the first latched input data in the higher voltage domain at the second latch node; and
the means for receiving the first latched input data is configured to receive the first latched input data from the second latch node.

13. A method for latching an input data signal in a flip-flop circuit, comprising:
receiving at an input stage, an input data signal on a data input in a lower voltage domain;
receiving at the input stage, a clock signal on a clock input;
receiving the clock signal at a gate electrode of a clock control transistor, the clock control transistor comprising a first current electrode and a second current electrode coupled to a first current electrode of a data control transistor;
receiving the input data signal at a gate electrode of the data control transistor, the data control transistor comprising the first current electrode coupled to the second current electrode of the clock control transistor, and a second current electrode;
generating a control signal based on an activation of the clock control transistor by the clock signal and the data control transistor by the input data signal;
storing a latched voltage as a first latched input data at a first latch node in a higher voltage domain than the lower voltage domain, based on the input data signal in response to the control signal;
latching the first latched input data as a second latched output data in a slave stage; and
outputting the second latched output data as a flip-flop output.

14. The method of claim 13, further comprising:
inverting the input data signal and providing an inverted input data signal in the lower voltage domain;
receiving the clock signal at a second clock control transistor of the flip-flop circuit;
receiving the inverted input data signal at a second data control transistor of the flip-flop circuit;
generating a second control signal based on an activation of the second clock control transistor by the clock signal and the second data control transistor by the inverted input data signal; and
storing the latched voltage as the first latched input data at the first latch node in the higher voltage domain, based on the input data signal in response to the control signal and the second control signal.

15. The method of claim 14, wherein storing the latched voltage based on the input data signal in response to the control signal and the second control signal comprises:
providing the first control signal to the first latch node comprised of a first node of a cross-coupled inverter circuit; and
providing the second control signal to a second node of the cross-coupled inverter circuit operating in the higher voltage domain.

16. The method of claim 15, further comprising:
receiving the input data signal at a gate electrode of a first transistor, the first transistor comprising a first current electrode coupled to a voltage source of the higher voltage domain, and a second current electrode coupled to a first inverter of the cross-coupled inverter circuit and to a power input of the first inverter, the first transistor configured to couple the voltage source of the higher voltage domain to the power input of the first inverter based on the input data signal;
receiving the inverted input data signal at a gate electrode of a second transistor, the second transistor comprising a first current electrode coupled to the voltage source of the higher voltage domain, and a second current electrode coupled to a second inverter of the cross-coupled inverter circuit, the second transistor configured to couple the voltage source of the higher voltage domain to a power input of the second inverter based on the inverted input data signal; and
receiving the clock signal at a gate electrode of a third transistor, the third transistor comprising a first current electrode coupled to the second current electrode of the first transistor and to the first inverter, and a second current electrode coupled to the second current electrode of the second transistor and to the second inverter for controlling a voltage supply from the voltage source of the higher voltage domain to the power input of the first inverter and to the power input of the second inverter based on the clock signal.

17. The method of claim 13, further comprising level-shifting the second latched output data from the higher voltage domain to the lower voltage domain, and providing the level-shifted second latched output data on the flip-flop output.

18. The method of claim 13, wherein the first latch node of the latch circuit is coupled to a control circuit at the first current electrode of the clock control transistor, and the control circuit is configured to provide the control signal at the first current electrode of the clock control transistor.

19. The method of claim 13 performed in an integrated circuit (IC).

20. The method of claim 13 performed in a device selected from the group consisting of: a set top box; an entertainment unit; a navigation device; a communications device; a fixed location data unit; a mobile location data unit; a mobile phone; a cellular phone; a computer; a portable computer; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; and a portable digital video player.
